(19) United States
(12) Patent Application Publication
(10) Pub. No.: US 2015/0236714 A1
(43) Pub. Date: Aug. 20, 2015

(54) METHOD AND DEVICE FOR COMPRESSING DIGITAL DATA

(71) Applicant: Electronics and Telecommunications Research Institute, Daejeon (KR)

(72) Inventor: Gweon Do JO, Daejeon (KR)

(73) Assignee: Electronics and Telecommunications Research Institute, Daejeon (KR)

(21) Appl. No.: 14/618,860

(22) Filed: Feb. 10, 2015

(30) Foreign Application Priority Data
Feb. 14, 2014 (KR) 10-2014-0017384

(51) Int. Cl. H03M 7/30; G06F 5/01

(52) U.S. Cl. CPC H03M 7/30; G06F 5/01

(57) ABSTRACT

Provided is a digital data compression method and device. A method of compressing digital data includes performing compressing by decreasing the sign bit extension of digital data, wherein bit extraction is performed based on a sample having the longest valid bit in a block and a shift left technique is selectively used.

### CROSS-REFERENCE TO RELATED APPLICATIONS

This U.S. non-provisional patent application claims priority under 35 U.S.C. §119 of Korean Patent Application No. 10-2014-0017384, filed on Feb. 14, 2014, the entire contents of which are hereby incorporated by reference.

### BACKGROUND OF THE INVENTION

The present invention disclosed herein relates to data compression, and more particularly to, a digital data compression method and device that compresses data converted into digital data.

Wireless communication is one of elements that make human being's life more productive and convenient.

Communication signals may be compressed in order to decrease traffic in wireless digital communication. For example, when it is assumed that fifteen bits are applied to the baseband I/Q sample of a communication signal, one of the simplest data compression techniques is removing some of lower bits including least significant bit (LSB). For example, when removing lower five bits from allocated fifteen bits, transmission data has ten bits.

However, since quantization noise increases in proportion to the number of removed bits, the decrease of signal transmission quality is caused.

A technique of decreasing the number of bits of a sign extension part for data compression has been proposed in the related field. That is, a block scaling technique has been proposed. However, the block scaling technique needs a division operation and a floating point operation. Thus, many operations are needed for data compression and a lot of time is needed to complete data compression.

### SUMMARY OF THE INVENTION

The present invention provides a digital compression method and device that has relatively less operations.

Embodiments of the present invention provide methods of compressing digital data including:
finding a maximum valid bit number from Nₛ (where Nₛ is a natural number equal to or larger than one) samples of M (where M is equal to or larger than three) bit digital data in a block; collectively extracting LSB data bits corresponding to a preset compression data bit number from the Nₛ samples when the maximum valid bit number is equal to or smaller than the preset compression data bit number, in first data compression step;
performing a shift left operation on the bits of a corresponding sample to be processed in the block by a first preset value, and performing a shift on marking operation on a corresponding bit of additional information B mapped to the corresponding sample, when the maximum valid bit number exceeds the preset compression data bit number and a bit number obtained by subtracting the valid bit number of the corresponding sample from the maximum valid bit number is equal to or larger than the first preset value, in a second data compression step; and performing a shift left operation on the bits of the corresponding sample by a second preset value, and performing a shift on marking operation on a corresponding bit of the additional information B, when the second preset value indicating a bit number obtained by subtracting the preset compression data bit number from the maximum valid bit is equal to or larger than one and smaller than the first preset value and a bit number obtained by subtracting the valid bit number of the corresponding sample from the maximum valid bit number is equal to or larger than the second preset value, in a third data compression step.

In other embodiments of the present invention, methods of compressing digital data include performing compressing by decreasing the sign bit extension of digital data, wherein bit extraction is performed based on a sample having the longest valid bit in a block and a shift left technique is selectively used.

In still other embodiments of the present invention, devices for compressing digital data include data compressor receiving and compressing digital sample data; and a transmitter transmitting compressed data output from the data compressor, wherein the data compressor includes:

a search module finding a maximum valid bit number from Nₛ (where Nₛ is a natural number equal to or larger than two) samples of M (where M is a natural number equal to or larger than three) bit digital data in a block; a first data compression module collectively extracting LSB data bits corresponding to a preset compression data bit number from the Nₛ samples when the maximum valid bit number is equal to or smaller than the preset compression data bit number;
a second data compression module performing a shift left operation on the bits of a corresponding sample to be processed in the block by a first preset value and performing a shift on marking operation on a corresponding bit of additional information B mapped to the corresponding sample, when the maximum valid bit number exceeds the preset compression data bit number and a bit number obtained by subtracting the valid bit number of the corresponding sample from the maximum valid bit number is equal to or larger than the first preset value; and
a third data compression module performing a shift left operation on the bits of the corresponding sample by a second preset value, and performing a shift on marking operation on a corresponding bit of the additional information B, when the second preset value indicating a bit number obtained by subtracting the preset compression data bit number from the maximum valid bit is equal to or larger than one and smaller than the first preset value and a bit number obtained by subtracting the valid bit number of the corresponding sample from the maximum valid bit number is equal to or larger than the second preset value.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is an exemplary diagram that represents a positive integer number by using eight bits;

FIG. 2 is an exemplary diagram that represents a negative integer number by using eight bits;

FIGS. 3 to 8 are exemplary diagrams that explain data compression according to the present invention;

FIG. 9 is a data compression flowchart according to the present invention;

FIG. 10 is a block diagram of a data compression device to which the present invention is applied; and

FIG. 11 is a detailed module block diagram of a data compressor of FIG. 10.

### DETAILED DESCRIPTION OF PREFERRED EMBODIMENTS

Exemplary embodiments of the present invention are described below in detail with reference to the accompanying drawings. It should be noted that only descriptions required for understanding operations according to various embodiments of the present invention are provided below and other descriptions are not provided in order not to obscure the subject matter of the present invention.

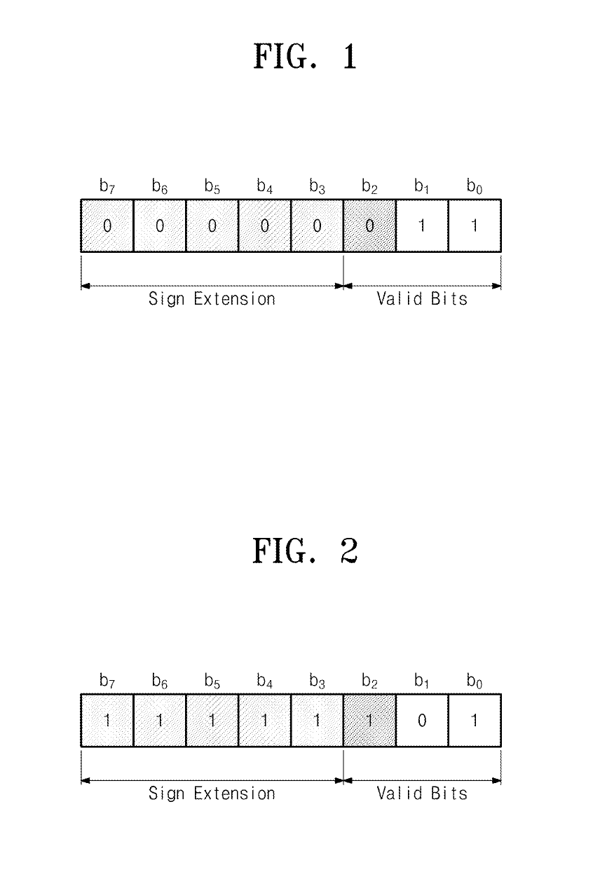

FIG. 1 is an exemplary diagram that represents a positive integer number by using eight bits and FIG. 2 is an exemplary diagram that represents a negative integer number by using eight bits.

When removing unnecessary parts from M (which is a natural number) bits that representing an integer number in a binary form, a data amount decreases. That is, data may be compressed.

The binary value of M bits includes sign bits and a bit row represents the size of a number. In particular, in a 2's complement representation technique, all bits excluding the bit row representing the size of a number are signal bits. Thus, valid bits are a 1-bit sign value and a bit row representing the size of a number and remaining bits are the simple extensions of a sign bit.

In FIG. 1, valid bits are lower three bits, most significant bit (MSB) of the three lower bits is a valid sign bit, and the remaining higher five bits “00000” of eight bits are simply extended sign bits.

FIG. 2 represents a negative integer number of −3 by using eight bits of 11111101. Valid bits are lower three bits, most significant bit (MSB) of the three lower bits is a valid sign bit, and the remaining higher five bits 11111 of eight bits are simply extended sign bits.

Thus, the sign extension part corresponding to the higher five bits may decrease for data compression.

For example, it is assumed that fifteen bits are allocated to the baseband I/Q sample of a communication signal (M=15). For data compression, I-channel thirty two samples are first defined as a unit block (Nₛ=32). When attempting to compress fifteen bit samples to ten bits (M_{c}=10), the simplest method of decreasing them to ten bits is removing LSB five bits. However, since signal quality decreases proportionally, there is a need for a more improved method.

Due to the characteristics of a communication signal, a valid bit number Kᵥ will vary from two bits to fifteen bits. That is, the number of sign extended bits may vary from 0 to 13.

While a value having a relatively little valid bit experiences a large communication quality decrease when using an LSB removal method, a value having a relatively many valid bit experiences a relatively small communication quality decrease by LSB removal.

In the case of an LTE signal, there are relatively many values having a little valid bit, since the values of its baseband I/Q channel have a Gaussian distribution form. Thus, a simple LSB removal method is not effective.

Thus, a block scaling techniques is known as one of methods of improving it. In the case of the block scaling technique, the size value of a sample having the maximum value in a block to be processed is defined as a scaling factor. The size values of samples that have no maximum value are divided by a scaling factor. A quantization level minimizing an error is obtained from the values obtained through a division. Data is compressed by performing such quantization.

However, since the block scaling technique involves a division operation and a floating point operation, many calculations are needed.

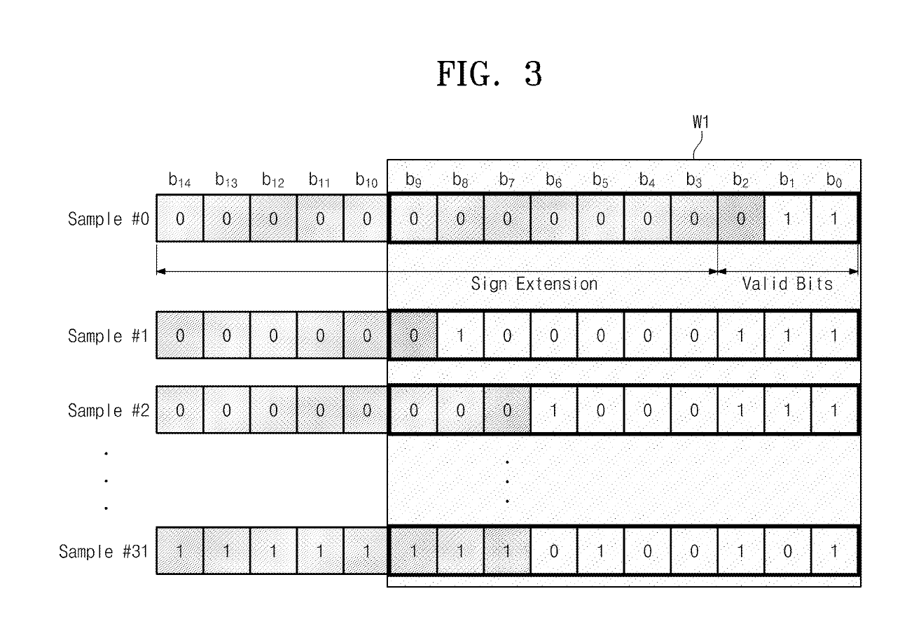

An embodiment of the present invention decreases the sign bit extension of data to achieve compression, and bit extraction is performed on a sample having the longest valid bit in a block and a shift left technique is additionally used. Data compression according to the present invention may be suitable for compressing data between the modem of a mobile communication system and an RF block. FIGS. 3 to 8 are exemplary diagrams that explain data compression according to the present invention.

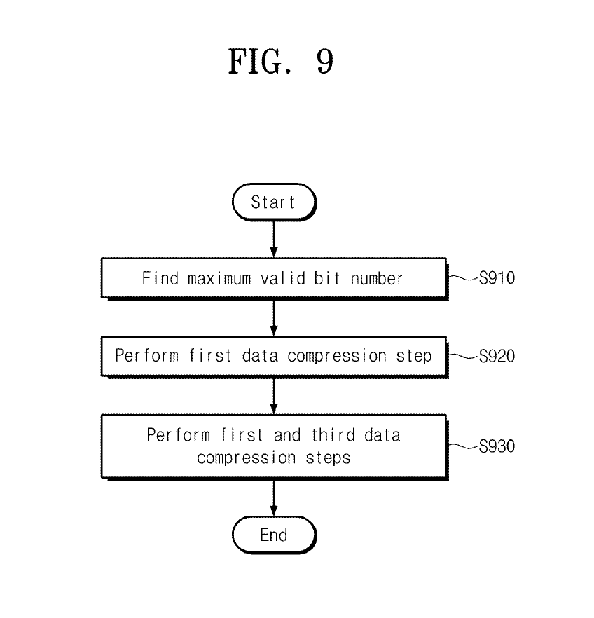

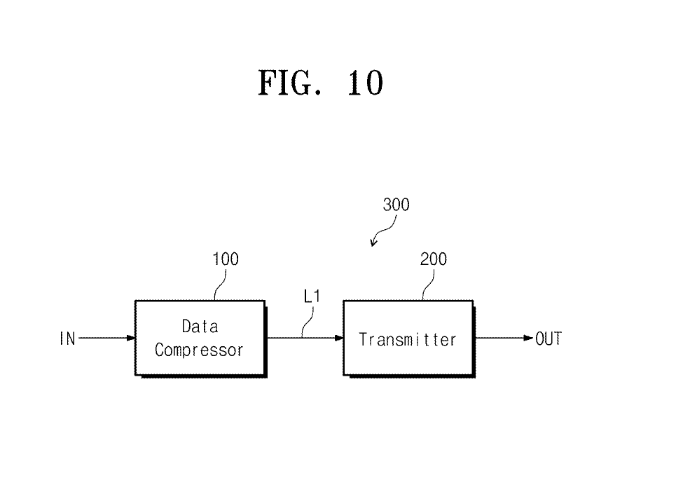

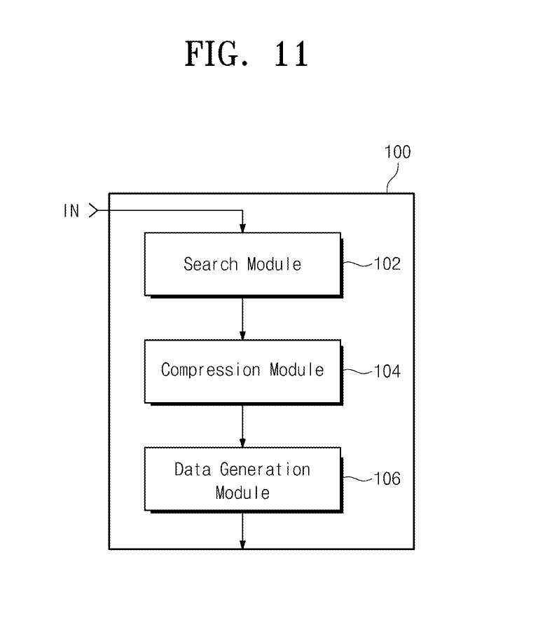

FIG. 9 is a data compression flowchart according to the present invention, and FIG. 10 is a block diagram of a data compression device to which the present invention is applied. FIG. 11 is a detailed module block diagram of a data compressor of FIG. 10.

As shown in FIG. 10, a data compression device to which the present invention is applied includes a data compressor 100 and a transmitter 200. Digital data applied through an input IN is compressed by the data compressor 100 and then is applied to the transmitter 200 through a line L1. The transmitter 200 transmits compressed output data to a corresponding channel through an output OUT. The data compressor 100 includes a search module 102, a compression module 104, and a data generation module 106 as shown in FIG. 11, in order to perform a data compression technique (flowchart of FIG. 9) according to an embodiment of the present invention.

Thus, it is possible to compress data with a simple bit operation without a complex operation such as a division operation. Also, since additional information is used, the quality decrease of compressed data is minimized or prevented.

Before explaining FIG. 3, the following terms are defined.

One block includes Nₛ (which is a natural number equal to or larger than two) samples. One sample includes M (which is a natural number equal to or larger than three) bits. Assume a case where certain bits are removed from M bits to obtain data having M_{c} bits.

In a block, assume a case where each of Nₛ (=32) samples, each of which includes M (=15) bits is compressed to M_{c} (=10) bits.

First, additional information A and additional information B (additional information—B) are defined. Information on the positions (or information that may infer the positions) of the valid sign bit of a sample having the maximum valid bit number in the block may be stored in the additional information A.

In addition, a collection of pieces of bit information mapped to samples in the block is defined as the additional information B. When there are Nₛ samples in the block, additional information B on up to Nₛ bits may be provided. When not 1:1 mapping but 1:N mapping is performed, the number of the bits of the additional information B (additional information—B) may be smaller than that of Nₛ bits.

Assume the number of the valid bits of a sample having the most (maximum) valid bit among all sample values in the block, as a maximum valid bit number.

In step S910 of FIG. 9, the maximum valid bit number is found among Nₛ (which is a natural number equal to or larger than two) samples of M (which is a natural number equal to or larger than three) bit digital data in a block.

In first data compression step S920, when the maximum valid bit number is equal to or smaller than a preset compression data bit number, LSB data bits are collectively extracted from the Nₛ samples by the compression data bit number.

Step S930 includes a second data compression step and a third data compression step. In the second data compression step, when the maximum valid bit number exceeds the preset compression data bit number and a bit number obtained by subtracting the valid bit number of a corresponding sample to be processed in the block from the maximum valid bit number is equal to or larger than a first preset value, the bits of the corresponding sample are shift left by the first preset value, and shift on marking is performed on a corresponding bit of the additional information B mapped to the corresponding sample. In the third data compression step, when a second preset value indicating a bit obtained by subtracting the preset compression data bit number from the maximum valid bit number is between 1 and the first preset value and a bit number obtained by subtracting the valid bit number of the corresponding sample from the maximum valid bit number is equal to or larger than the second preset value, the bits of the corresponding sample are shift left by the second preset value, and shift on marking is performed on a corresponding bit of the additional information B.

Step S910 may be performed by the search module 102 of FIG. 11. Also, steps S920 and S930 may be performed by the compression module 104 of FIG. 11.

Step S920 is the first data compression step that is performed when the maximum valid bit number is smaller than or equal to the preset compression data bit number.

For example, as shown in FIG. 3 to which window W1 is applied, when the maximum valid bit number (Kᵥ_{_{—}}ₘₐₓ) in a block is smaller than or equal to 10 bits, the data compressor 100 collectively extracts LSB M_{c} bits from all samples in the block.

The window W1 is a window for obtaining M_{c} bits. That is, the desired number of the preset bits of compression data is e.g. ten in this example.

In addition, the number of samples in the block is e.g. thirty two in FIG. 3.

The position information of the valid sign bit of a sample having the maximum valid bit number in the block is stored in the additional information A. Thus, information compressed by the completion of a compression procedure may include Nₛ samples including M_{c} bits and the additional information A.

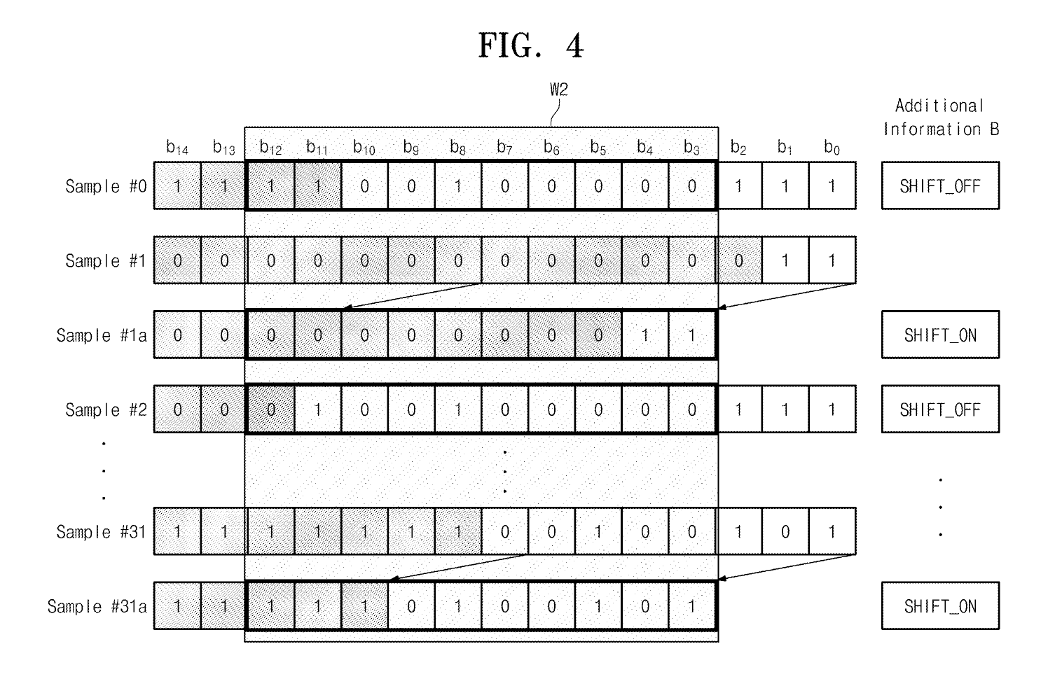

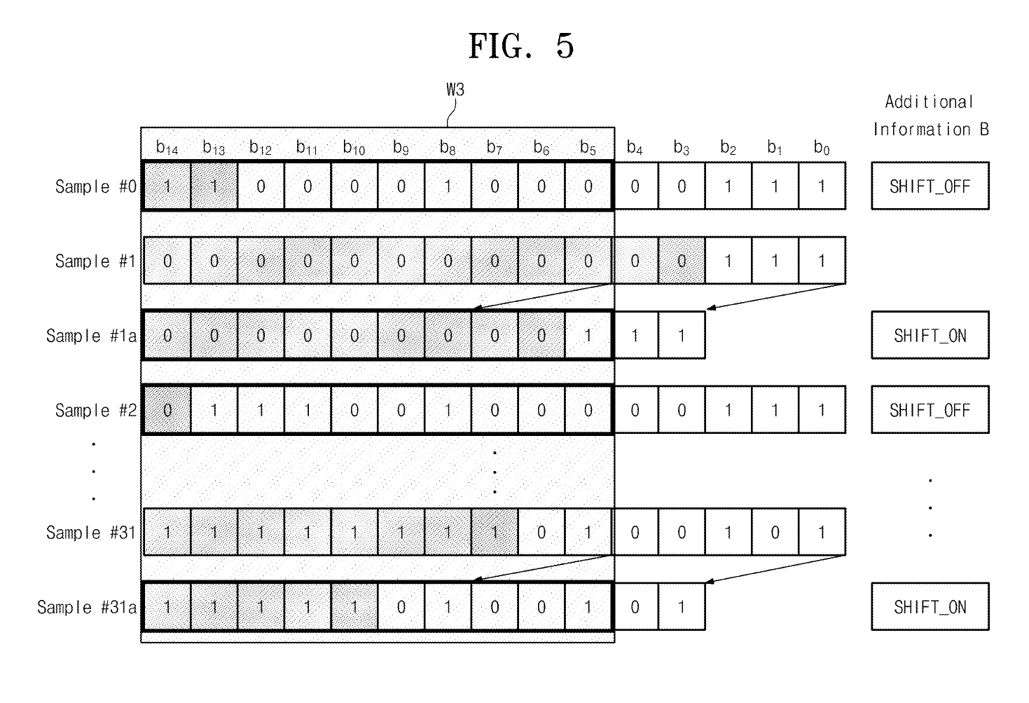

As shown in FIG. 4 or 5, a case where the maximum valid bit number Kᵥ_{_{—}}ₘₐₓ in a block exceeds M_{c} bits is discussed.

When the valid bit number of a specific sample is smaller or lager than the maximum valid bit number in a corresponding block by the preset N_{d} (which is e.g., three) bits, a corresponding sample is shift left by N_{d} bits and then SHIFT_ON is marked on the corresponding bit of the additional information B mapped to the corresponding sample.

In this example, N_{d} may be referred to as the first preset value.

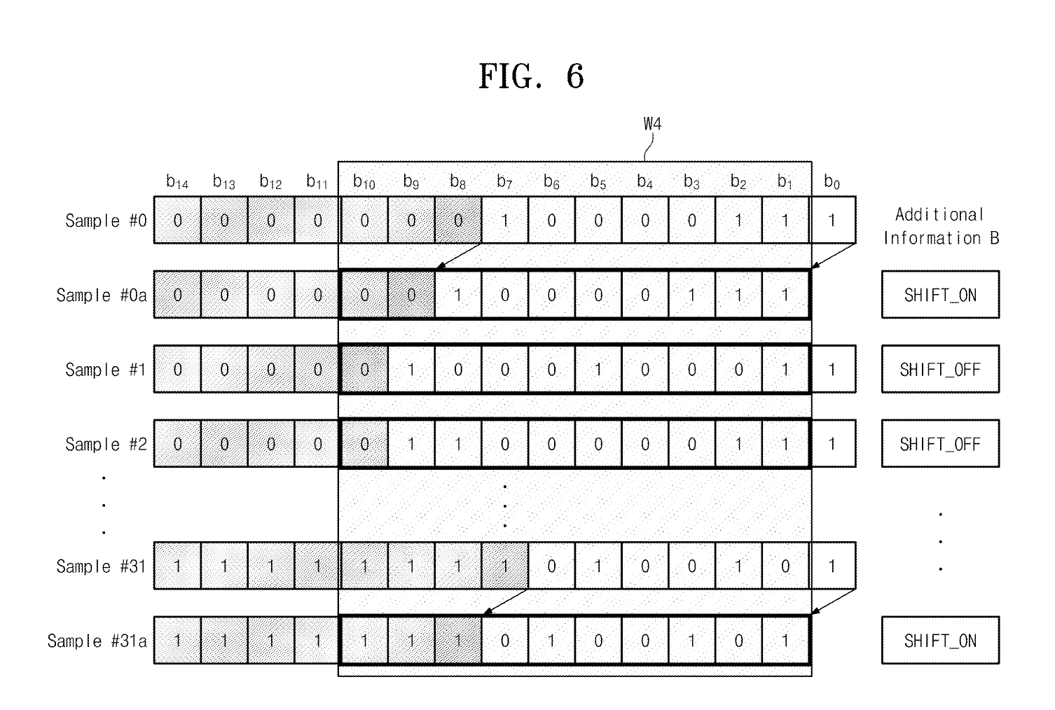

However, as shown in FIG. 6, when the difference BT between the maximum valid bit number Kᵥ_{_{—}}ₘₐₓ in a block and a bit number M_{c} to be extracted is equal to or larger than 1 and smaller than N_{d}, a specific sample is shift left by BT bits and SHIFT_ON is marked on the corresponding bit of the additional information B, only when the valid bit number of a corresponding sample is smaller or larger than the maximum valid bit number in a corresponding block by a value equal to or larger than BT bits. In other cases, SHIFT_OFF is marked on the corresponding bit of the additional information B. In this example, BT may be referred to as the second preset value.

After completing the above-described shift left process, lower M_{c} bits are extracted on all samples continuously starting from the position of the valid sign bit of a sample having the maximum valid bit number in a block.

That is, when the maximum valid bit number in a block is 15 bits (M=15), ten bits (M_{c}=10) such as b14, b13, b12, . . . . B5 are extracted.

Information compressed through the compression process completed as described above includes Nₛ samples including M_{c} bits, the additional information A and the additional information B.

Although it has been assumed so far that the total number of bits of the additional information B are the same as the number of samples in a block, the following variations may be implemented when there is a need to further decrease the size of the additional information B. That is, when there are Nₛ samples in a block, each bit may not be mapped to one sample but many sampled.

For example, when mapping is performed to two samples, the additional information B decreases to Nₛ/2 bits that are the half of Nₛ bits.

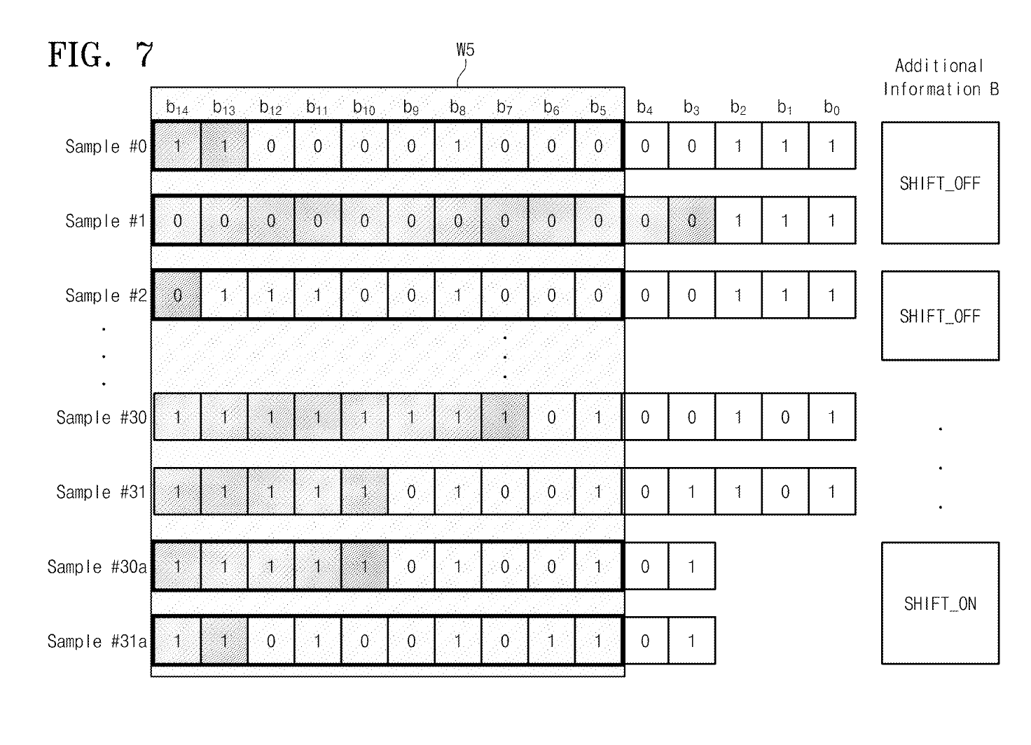

In this case, when the maximum valid bit number of specific two samples in a block is smaller or larger than the maximum valid bit number in a corresponding block by a value equal to or larger than N_{d} bits (e.g., three bits) as shown in FIG. 7 employing window W5, corresponding two samples all are shift left by N_{d} bits (e.g., three bits) as shown in FIG. 7 employing window W5 and then SHIFT_ON is marked on the corresponding bit of the additional information B mapped to corresponding two samples.

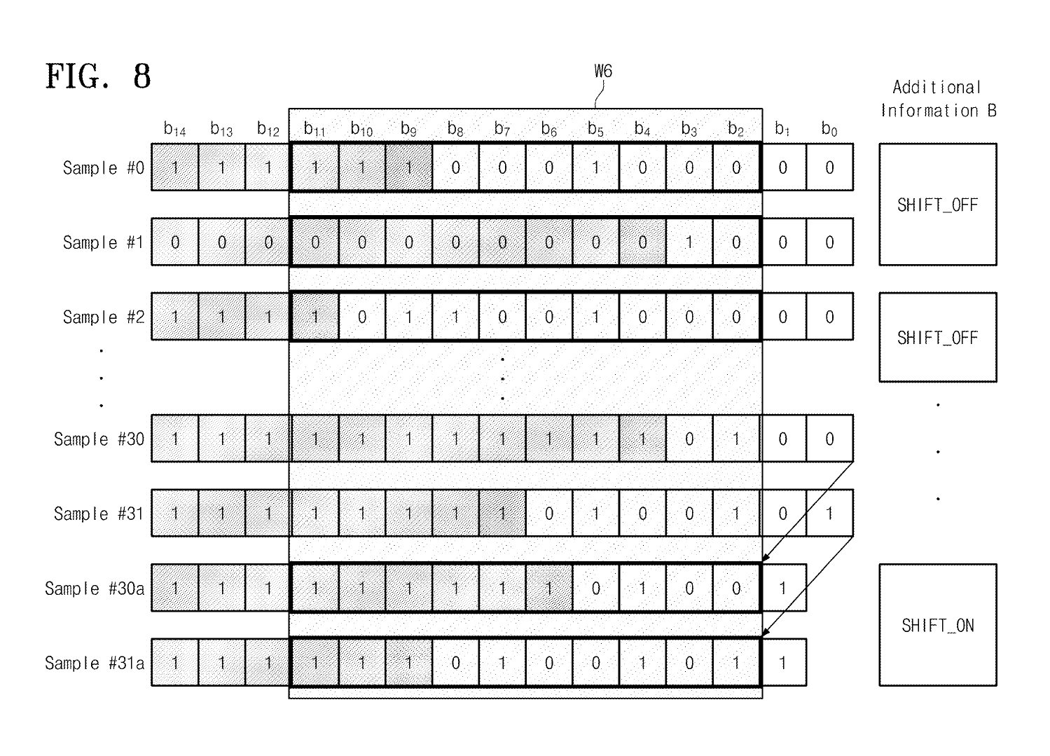

However, when the difference BT between the maximum valid bit number in a block and a bit number M_{c} (=10) to be extracted is equal to or larger than 1 and smaller than N_{d}, two specific samples are shift left by BT bits and SHIFT_ON is marked on the corresponding bit of the additional information B, only when the maximum valid bit number of corresponding two specific samples is smaller or larger than the maximum valid bit number in a corresponding block by a value equal to or larger than BT bits as shown in FIG. 8 employing window W6. In other cases, SHIFT_OFF is marked on the corresponding bit of the additional information B.

The digital data compressed by using the above-described technique may be recovered by inversely performing the compression process and it may be implemented by a person skilled in the art.

Also, the present invention is a technology for compressing data and may be combined with other technology having similar objectives.

The present invention may be fundamentally applied to the digital sample data of a communication system and may be applied to all fields that need loss data compression.

As described above, according to the present invention, there is an advantage in that it is possible to achieve data compression with a simple bit operation without complex calculations such as a division operation. Thus, it is simple, easy and intuitive to implement the present invention. Also, there is an effect that reduces a quality decrease of compressed data by using additional information.

While particular embodiments have been described in the detailed description of the present invention, many variations may be made without departing from the scope of the present invention.

Therefore, the scope of the present invention should not be limited to the above-described embodiments but be defined by the following claims and equivalents thereof.

What is claimed is:

1. A method of compressing digital data, the method comprising:
finding a maximum valid bit number from Nₛ (where Nₛ is a natural number equal to or larger than one) samples of M (where M is equal to or larger than three) bit digital data in a block;
collectively extracting LSB data bits from the Nₛ samples under a first preset condition, in first data compression step;
performing a shift operation on the bits of a corresponding sample and performing a shift on marking operation on a corresponding bit of additional information B mapped to the corresponding sample, when a subtraction bit number is equal to or larger than a first preset value under a second preset condition, in a second data compression step; and
performing a shift operation on the bits of the corresponding sample and performing a shift on marking operation on a corresponding bit of the additional information B, when a the subtraction bit number is equal to or larger than a second preset value under a third preset condition, in a third data compression step.

2. The method of claim 1, wherein the first data compression step further comprises allocating position information on a sign bit of a sample having the maximum valid bit number in the block, to additional information A.

3. The method of claim 2, wherein the second data compression step further comprises marking shift off on a corresponding bit of the additional information B mapped to the corresponding sample without shift of the bits of the corresponding sample to be processed in the block, when a bit number obtained by subtracting the valid bit number of the corresponding sample from the maximum valid bit number is smaller than the first preset value.

4. The method of claim 3, wherein the third data compression step further comprises marking shift off on a corresponding bit of the additional information B without shift of the bits of the corresponding sample, when a bit number obtained by subtracting the valid bit number of the corresponding sample from the maximum valid bit number is smaller than the second preset value.

5. The method of claim 1, wherein the maximum valid bit number may vary depending on a block and includes a sign bit and a bit row that represents the size of a number.

6. The method of claim 5, wherein the data compression steps are performed between a modem and an RF block.

7. The method of claim 6, further comprising:
extracting, after completing shift left, LSB data bits corresponding to the compression data bit number, continuously starting from a position of a sign bit of a sample having the maximum valid bit number from the Nₛ samples, respectively; and
generating Nₛ samples, each of which is configured with the preset compression data bit number, the additional information A and the additional information B by the extraction, as the compression data information on the block compressed.

8. The method of claim 3, wherein the additional information B is smaller than the number of the samples when 1:N mapping is implemented.

9. The method of claim 1, wherein the first preset condition indicates when the maximum valid bit number is equal to or smaller than a preset compression data bit number,
the second preset condition indicates when the maximum valid bit number exceeds the preset compression data bit number, and
the third preset condition indicates when the second preset value indicating a bit number obtained by subtracting the preset compression data bit number from the maximum valid bit number is equal to or larger than one and smaller than the first preset value.

10. A device for compressing digital data, the device comprising:
data compressor receiving and compressing digital sample data; and
a transmitter transmitting compressed data output from the data compressor,
wherein the data compressor comprises:
finding a maximum valid bit number from Nₛ (where Nₛ is a natural number equal to or larger than two) samples of M (where M is a natural number equal to or larger than three) bit digital data in a block;
collectively extracting LSB data bits from the Ns samples under a first preset condition, in first data compression step;
performing a shift operation on the bits of a corresponding sample and performing a shift on marking operation on a corresponding bit of additional information B mapped to the corresponding sample, when a subtraction bit number is equal to or larger than a first preset value under a second preset condition, in a second data compression step; and
performing a shift operation on the bits of the corresponding sample and performing a shift on marking operation on a corresponding bit of the additional information B, when a the subtraction bit number is equal to or larger than a second preset value under a third preset condition, in a third data compression step.

11. The device of claim 10, wherein the data compressor compresses data between a modem of a mobile communication system and an RF block.

12. The device of claim 11, wherein the maximum valid bit number varies depending on a block.

13. The device of claim 10, wherein the first condition indicates when the maximum valid bit number is equal to or smaller than the preset compression data bit number,
the second condition indicates when the maximum valid bit number exceeds the preset compression data bit number, and
the third condition indicates when the second preset value indicating a bit number obtained by subtracting the preset compression data bit number from the maximum valid bit is equal to or larger than one and smaller than the first preset value.
